(19) United States
(12) Patent Application Publication
(10) Pub. No.: US 2026/0163263 A1
(43) Pub. Date: Jun. 11, 2026

(54) ELECTRONIC HOUSING FOR AN AUXILIARY UNIT

(71) Applicant: Brose Fahrzeugteile SE & Co. Kommanditgesellschaft, Würzburg, Würzburg (DE)

(72) Inventors: Steve Eberlein, Hallstadt (DE); Peter Sudermann, Würzburg (DE); Peter Buckmüller, Bamberg (DE)

(21) Appl. No.: 18/705,672

(22) PCT Filed: Oct. 24, 2022
(86) PCT No.: PCT/EP2022/079597

§ 371 Date: Apr. 29, 2024

(30) Foreign Application Priority Data
Oct. 28, 2021 (DE) 10 2021 212 198.5

(51) Int. Cl. H01R 9/16; F04B 17/03; H01R 9/22; H05K 5/06

(52) U.S. Cl. CPC H01R 9/16; H01R 9/223; H05K 5/064; F04B 17/03

(57) ABSTRACT

An electronics housing for an auxiliary unit of a motor vehicle has a metal lead frame with at least one connection contact. The lead frame is encapsulated as an insert with a plastic material of a housing part. At least sections of the connection contact project out of the housing part. The connection contact is enclosed by a potting pocket formed integrally on the housing part. A hardened potting compound is filled into the potting pocket. The connection contact has a form-fit contour which creates a form-fit between the connection contact and the potting compound so that shear forces and/or tensile forces occurring during thermal expansion are reduced between the connection contact and the potting compound.

The invention relates to an electronics housing for an auxiliary unit of a motor vehicle, having an encapsulated lead frame with at least one non- encapsulated terminal contact, wherein the terminal contact sits in a potting pocket filled with a cured potting compound. The invention furthermore relates to an auxiliary unit for a motor vehicle. The auxiliary unit is, for example, a fluid pump, in particular an electric oil pump.

An electric oil pump and in particular also a so-called booster or additional pump serves to deliver oil for open-loop control tasks or for cooling for in particular moving parts or components, for example also of a vehicle powered by an internal combustion engine, a hybrid drive, or an electric drive. Because of its delivery properties, such an oil pump usually generates an oil circuit with a pressure flow and a volume flow. A booster or additional pump driven, for example, electrically or by an electric motor is frequently used for at least intermittent lubrication or additional lubrication of transmission parts of a vehicle transmission, in particular of an automatic transmission. The delivered oil serves also to cool the components of additional components of the drive train of such a vehicle.

For open-loop and closed-loop control purposes, such an oil pump conventionally comprises a pump electronics system. The pump electronics system has, inter alia, an electronic circuit, sensors, and/or an electronic connection to a cable harness of the vehicle, and often electrical interfaces for activating actuators. The pump electronics system is installed suitably inside an essentially closed housing shell of an electronics housing. The electrical connections and interfaces are typically implemented by one or more plugs which project at least partially through the electronics housing and thus provide an electrically conductive connecting option between the pump electronics system inside the housing shell and, for example, motor lines of the electric motor. In a typical installed situation, the electronics housing, and thus the pump electronics system, is arranged together with the oil pump in the oil sump of the vehicle transmission. The electronics housing here lies completely or at least partly directly in the oil.

In order to protect the sensitive pump electronics system, it is for example known to use hermetically sealed steel housings as the electronics housings from which glazed pins project as plugs for electrical coupling of the pump electronics system. However, housings known, for example, from DE 195 15 10 622 A1 or DE 10 2013 220 599 A1 are preferably used which are often produced in a two-component injection-molding method. A lead frame, as a pre-molded part or insert, is here encapsulated with an electrically non- conductive thermoplastic. The plug formed as a result is then encapsulated with the plastic of the housing shell in a second injection-molding method. In both injection-molding methods, a similar plastic, preferably a polyamide, polybutylene terephthalate, or polyphenylene sulfide material is typically used. A mechanically stable and electrically safe electronics housing is consequently provided in which the pump electronics system can be enclosed in an operationally reliable fashion.

Such electronics housings need to be designed or structurally configured for relatively large temperature ranges. The temperature range in the oil sump which needs to be managed or to be taken into account is typically between, for example, −40° C. and +130° C. It also needs to be taken into account here that the lubricant used (oil) has a viscosity which is temperature-dependent and decreases as the temperature increases, i.e. is greater at lower temperatures than at higher temperatures. The lubricant or oil used can moreover have aggressive additives which can attack and damage the electronics.

In particular at higher operating temperatures or at temperatures which rise because of operation, the risk of leaks therefore also increases. The reason for this is that, on one hand, avoiding leaks requires a correspondingly sealed electronics housing, whilst, on the other hand, because of the high temperature fluctuations, expansions of the housing, i.e. different expansions of the electronics housing and/or the plugs at increasing temperatures and hence falling viscosity of the oil or lubricant used, increasingly tend to cause leaks, for which there is a relatively less pronounced tendency at low temperatures and thus high viscosity of the oil or lubricant. Changes in pressure of the air enclosed in the electronics housing disadvantageously amplify such tendencies to leaks such that high mechanical demands are placed on the fluidtightness of the electronics housing.

In particular in the region of the encapsulated lead frame, capillary gaps or cracks between the plastic of the encapsulation and the metal lead frame often occur here, through which the oil can penetrate into the electronics housing. The formation of gaps when plastic-encapsulated lead frames are under thermal load is here caused by different coefficients of expansion of the connected materials. Depending on the direction in which the expansion manifests to the greater extent, the materials become detached from each other either by shearing or by tensile stress.

Plastic-encapsulated metal inserts in electronics housings therefore often become non-leaktight after being subject to a thermal load just once because a gap between the metal and the plastic is formed by the thermomechanical expansion. Foreign media can then penetrate into the electronics space through this gap and cause corrosion.

These gaps have hitherto been sealed in a time-consuming fashion by additional processes (potting, impregnating, etc) outside and/or inside the electronics housing around the plug in order to protect the electronics internal space from foreign media. It is thus known, for example, from DE 10 2011 085 26 054 A1 that, in the case of a lead frame encapsulated with a thermoplastic, a thermoset or a liquid silicone adhesive is introduced to provide a seal between the plastic and the lead frame. The additional sealing requires an additional manufacturing step during production and thus entails additional costs.

A further customary sealing measure is, for example, the use of a potting agent, i.e. a cured potting compound or potting material. For this purpose, the plug is arranged in a molded potting pocket which is filled with a liquid potting compound and is then cured. The potting agent or the potting compound here generally has good adherence or adhesion properties both with respect to the plastic of the electronics housing or the potting pocket and also with respect to the metal of the lead frame such that the sealing in the region at risk of leaks is improved.

However, when there is a change in temperature, mechanical stresses and forces also occur in the potting agent at the boundary surfaces with the plastic and the metal. As a result, these additional seals are likewise subject to the formation of gaps which, although they are slower to occur, can likewise result in instances of a lack of leaktightness at this interface when there are a high number of changes in temperature.

EP 3 007 330 B1 discloses a direct current motor with an oil-tight housing part which separates an electronics space from a motor space through which oil circulates. In order to electrically contact motor electronics of the electronics space with a stator winding in the motor space, a number of metal guide plates are provided which traverse the housing part perpendicularly. The guide plates are encapsulated or potted with the plastic material of the housing part and here have a form-fitting contour which effects a form-fitting fastening of the guide plates in the housing part.

DE 10 2013 212 166 A1 discloses an electronics housing with a metal lead frame, encapsulated with plastic, which sits with a plug in a potting pocket filled with a potting compound. In order to reduce the mechanical stresses in the region of the potted plug, and thus to improve the sealing, the lead frame is provided in the encapsulated region with a form-fitting contour which effects a form fit between the lead frame and the plastic material. As a result, a zero point relevant for the thermal expansion is effectively achieved. The form fit is here arranged as close as possible to the potted region such that the absolute expansion of the lead frame and the plastic in the potted region is as low as possible, as a result of which the thermomechanical stress on the potting agent is reduced and the sealing thus improved.

The object of the invention is to specify a particularly suitable electronics housing for an auxiliary unit of a motor vehicle. In particular, it is intended that leaktight encapsulation of metal inserts is achieved over a longer lifetime without any additional seals. The object of the invention is furthermore to specify a particularly suitable auxiliary unit with such an electronics housing.

In terms of the electronics housing, the object is achieved according to the invention with the features of claim 1 and in terms of the auxiliary unit with the features of claim 6. Advantageous embodiments and developments are the subject of the dependent claims. The advantages and embodiments mentioned in terms of the electronics housing are transferable analogously to the auxiliary unit too, and vice versa.

The electronics housing according to the invention is provided for an auxiliary unit of a motor vehicle, in particular for a fluid pump, preferably for an electric oil pump, for example for a booster or additional pump, and is suited and configured therefor. The electronics housing here has a metal lead frame with at least one terminal contact or plug, wherein the lead frame is encapsulated as a (metal) insert with a plastic material of a housing part, and wherein the terminal contact projects at least partially from the housing part or from the (plastic) encapsulation. The lead frame is here preferably configured as a stamped and bent part.

The housing part here has a potting pocket molded integrally, i.e. as a single piece or monolithically, in which the terminal contact sits. The potting pocket is here filled with a cured potting compound, for example an epoxy resin. In other words, a liquid potting compound or potting material has flowed around the terminal contact and the potting compound has then been cured.

According to the invention, the terminal contact or plug of the lead frame has a form-fitting contour which effects a form fit between the terminal contact and the cured potting compound such that shearing and/or tensile forces between the terminal contact and the potting compound, occurring in the course of thermal expansion are reduced. A particularly suitable electronics housing is achieved as a result.

The conjunction “and/or” is to be understood here and below such that the features linked by means of this conjunction can be formed both jointly and as alternatives to each other.

A “form fit” or a “form-fitting connection” between at least two interconnected parts is understood here and below in particular to mean that the interconnected parts are held together at least in one direction by direct mutual engagement of contours of the parts themselves or by indirect mutual engagement via an additional connecting part. A reciprocal movement in this direction is thus “blocked” because of their shape.

According to the invention, a structuring of the shape of the potted terminal contact or plug is provided. By virtue of the additional shaping of the lead frame or the terminal contact, the shearing and/or tensile forces between the materials (metal of the plug—potting compound, potting compound—plastic of the potting pocket or the housing part) are reduced by more regions with a form fit of the potting compound being available and the cohesive forces can therefore better counteract formation of gaps. The sealing of the electronics housing is improved as a result.

The housing part is configured as an injection-molded part. A thermoplastic material is preferably used for this purpose which is chemically inert with respect to contact with a fluid (oil) delivered by the auxiliary unit, preferably a polyamide (PA), polybutylene terephthalate (PBT) material, or polyphenylene sulfide (PPS) material. A mechanically stable housing part is supplied as a result. In particular, a housing part made of PPS (for example, Fortron 4332L6 ) and a terminal contact or lead frame made of high-performance copper (CuCrAgFeTiSi, UNS number C18080) are used. The potting agent is here preferably an epoxy resin (for example, ES4322) which has a low coefficient of thermal expansion (CTE). In the cured state, the epoxy resin here has a low modulus of elasticity (Young's modulus) despite its high hardness, as a result of which mechanical stresses at the connection with the terminal contact are reduced.

In one conceivable embodiment, the housing part has a CTE of 12 ppm/K (parts per million per degree Kelvin) and the lead frame a CTE of 17 ppm/K, and the potting agent a CTE of 26 ppm/K. When there is no form-fitting contour according to the invention present, this results, for example, in mechanical stresses in the region of the connecting plug of, for example, 30 MPa (megapascals). The form-fitting contour is here preferably configured in such a way that the terminal contact and the cured potting compound are in form-fitting engagement, as a result of which the terminal contact and the potting compound cannot be displaced relative to each other, or only insignificantly, in the course of thermal expansion.

In one advantageous embodiment, the form-fitting contour is introduced as at least one recess in the terminal contact. The form-fitting contour is preferably introduced into the terminal contact as at least one recess closed on all sides, i.e. as a hole, a through opening, or as an aperture. The form-fitting contour is here introduced into the terminal contact or the lead frame, for example by means of stamping. In other words, a perforation is introduced into the terminal contact for the purpose of optimizing sealing. By virtue of introducing recesses, the potting/sealing compound flows around the terminal contact in such a way that the potting compound traverses the terminal contact in a direction oriented transversely to the longitudinal direction. In other words, the recess in the region to be potted makes it possible for the potting compound to be able to flow into itself. As a result, the formation of gaps or cracks is avoided or at least reduced not just by adhesion of the potting compound to the lead frame/terminal contact and instead also by cohesion in the potting compound itself.

The reduction of the shearing and tensile forces by introducing the aperture-like recess(es) therefore makes it possible to preserve leaktight encapsulations without additional seals over a longer lifetime than is possible in the case of conventional injection-molded parts. As a result, a saving can be made in additional sealing processes and materials if the quality of the encapsulation, with the provisions described here, already obtains a sufficient sealing effect. A saving in material can thus be made and additional equipment and processes can be dispensed with.

one conceivable embodiment, the terminal contact is configured as a press-fit contact, wherein the press-fit portion projects from the potting compound.

In a particularly fluidtight embodiment, the lead frame embedded in the housing part has a step-like offset, i.e. a double bend, in the region of the potting pocket. This means that, in addition to the form-fitting contour in the potted region, a bending structure is provided in the encapsulated region. The offset prevents the terminal contact from slipping in the potting material, as a result of which the thermomechanical stresses in the course of thermal expansion of the materials are further reduced.

The auxiliary unit according to the invention is configured in particular as a fluid pump, preferably as an electric oil pump, for a motor vehicle. The auxiliary unit here has an abovedescribed electronics housing. As a result, a particularly suitable auxiliary unit is obtained in which the risk of a leak from the electronics housing is advantageously and simply avoided.

The auxiliary unit or the oil pump is preferably an electromotive booster or additional pump for a motor vehicle, in particular an oil pump for lubricating transmission parts of a vehicle transmission. The fluid delivered is here expediently oil, for example ATF oil (automatic transmission fluid) and serves, for example, also to cool the components or additional components of a drive train of such a motor vehicle. The term oil is here in particular not to be understood as being restricted to mineral oils. Rather, a fully or partly synthetic oil, a silicone oil, or other oil-like liquids such as, for example, a hydraulic liquid or a cooling lubricant can also be used.

An exemplary embodiment of the invention will be explained in detail below on the basis of the drawings, in which:

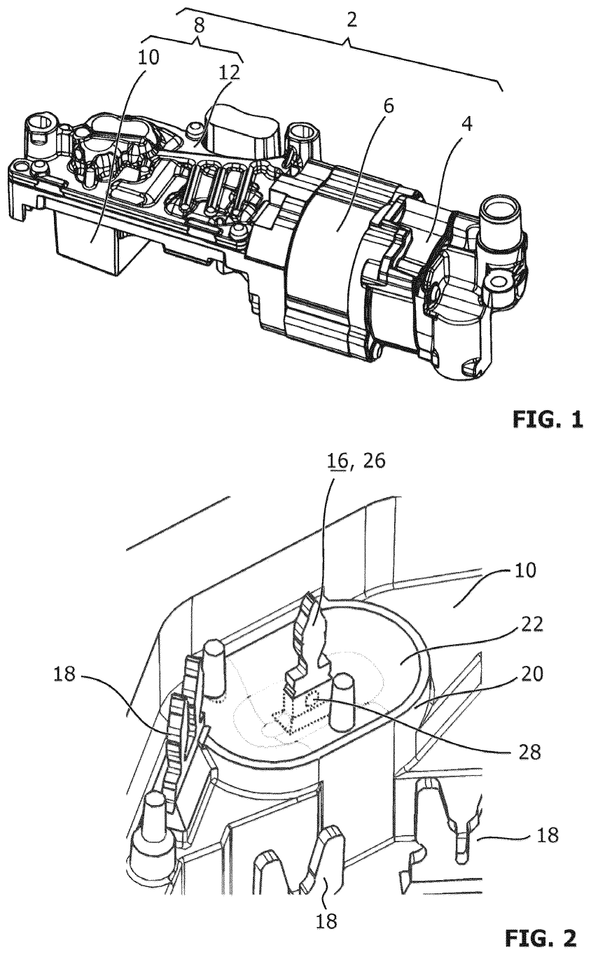

FIG. 1 shows in a perspective view an oil pump with a pump head and a drive, as well as an electronics housing,

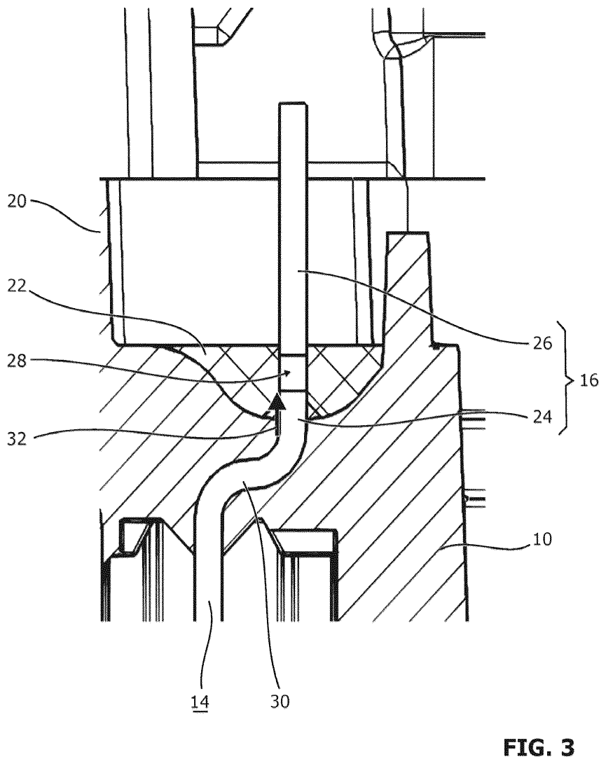

FIG. 2 shows in a perspective view a portion of the electronics housing with a view of a potting pocket with a terminal contact, and

FIG. 3 shows in a view in section a portion of the electronics housing.

Mutually corresponding parts and sizes are always provided with the same reference signs in all the FIG.

The auxiliary unit 2 shown in FIG. 1 is configured as a pump unit, in particular as an electric oil pump. The auxiliary unit 2 here has a pump head 4 and an electromotive drive 6 as well as an electronics housing 8.

A gerotor is, for example, accommodated as a delivery device in the pump head 4. The drive 6 is arranged on the front side of the pump head 4. The drive 6 is here configured as a brushless electric motor, in particular as an internal rotor with a stator without a housing. The drive 6 or the electric motor is coupled to an electronics system, not shown in detail, which is arranged in the electronics housing 8.

The electronics housing 8 here has essentially two housing parts 10, 12. The housing part 10 is configured as a function carrier or motor support. The housing part 10 is here configured as a plastic injection-molded part in which a lead frame 14 (FIG. 3) is embedded as an insert part. In other words, the lead frame 14 is at least partially encapsulated with the material of the housing part 10. The housing part 12 is configured as a metal housing or cooling cover. The housing part 12 is here configured in particular as an aluminum die-cast part.

The lead frame 14 has a number of terminal contacts 16, 18 which project from the housing parts 10. In the illustrations in FIG. 2 and FIG. 3, a terminal contact 16 in the form of a press-fit contact is shown, for example. Also illustrated in FIG. 2 are terminal contacts 18 in the form of clamping contacts for contacting capacitors and/or inductors.

The housing part 10 has a potting pocket 20 molded integrally, i.e. as a single piece or monolithically, in which the terminal contact 16 sits. The potting pocket 20 is here filled with a cured potting compound 22, for example an epoxy resin. The terminal contact 16 here has a portion 24 around which the potting compound 22 flows or which is embedded in the potting compound 22, and a portion 26, forming the press-fit region, which projects from the potting compound 22.

The terminal contact 16 here has in the portion 24 a form-fitting contour 28 which effects a form fit between the terminal contact 26 and the cured potting compound 22 such that shearing and/or tensile forces between the terminal contact 16 and the potting compound 22, occurring in the course of thermal expansion, are reduced.

The form-fitting contour 28 is here configured as a recess closed on all sides, i.e. as a hole, a through opening, or as an aperture which is introduced into the potted portion 24 of the terminal contact 16.

As can be seen in particular in the view in section of FIG. 3, the lead frame 14 embedded in the housing part 10 has a step-like offset 30, i.e. a double bend, in the vicinity of the potting pocket 22. The offset 30 prevents the terminal contact 16 from slipping in the potting material 22.

During operation of the auxiliary unit, changes in temperature, and thus thermomechanical stresses, can occur because of the different thermal expansions of the lead frame 12, the housing part 10, and the potting compound 22. This can result in the formation of cracks or gaps 32 in particular in the interface region between the lead frame 12 and the housing part 10, this being illustrated schematically by an arrow in FIG. 3.

The formation of cracks 32 here runs in the longitudinal direction of the terminal contact 16, i.e. at the interface of the surfaces of the lead frame 14 and the housing part 10 or the potting compound 22. The formation of cracks 32 along the surface is here interrupted when the crack meets the aperture-like form-fitting contour 28 in the portion 24. A more or less perpendicular change in direction of the surface is present here and the potting compound 22 additionally counteracts the formation of gaps by cohesion.

The claimed invention is not restricted to the abovedescribed exemplary embodiment. Instead, other variants of the invention can also be derived by a person skilled in the art within the scope of the disclosed claims without going beyond the subject-matter of the claimed invention. In particular, all the individual features described in connection with the exemplary embodiment can moreover also be combined in other fashions without going beyond the subject-matter of the claimed invention.

### LIST OF REFERENCE SIGNS

2 auxiliary unit
4 pump head
6 drive
8 electronics housing
10 housing part
12 housing part
14 lead frame
16 terminal contact
18 terminal contact
20 potting pocket
22 potting compound
24 portion
26 portion
28 form-fitting contour
30 offset
32 formation of cracks/gaps

1-6. (canceled)

7. An electronics housing for an auxiliary unit of a motor vehicle, the electronics housing comprising:
a housing part formed of plastic material;
a metal lead frame encapsulated as an insert in said plastic material of said housing part;
said metal lead frame having at least one terminal contact projecting at least partially from said housing part;
said terminal contact being surrounded by a potting pocket molded integrally on said housing part;
a cured potting compound filling said potting pocket; and
said terminal contact being formed with a form-fitting contour that effects a form fit between said terminal contact and said potting compound to thereby reduce shearing forces and/or tensile forces between said terminal contact and said potting compound that occur in a course of thermal expansion.

8. The electronics housing according to claim 7, wherein said form-fitting contour is at least one recess formed in said terminal contact.

9. The electronics housing according to claim 7, wherein said form-fitting contour formed in said terminal contact is at least one recess that is closed on all sides.

10. The electronics housing according to claim 7, wherein said terminal contact is a press-fit contact.

11. The electronics housing according to claim 7, wherein said lead frame embedded in said housing part is formed with a step-shaped offset in a region of said potting pocket.

12. An auxiliary unit of a motor vehicle, comprising an electronics housing according to claim 7.
